(19) United States
(12) Patent Application Publication
(10) Pub. No.: US 2010/0191492 A1
(43) Pub. Date: Jul. 29, 2010

(54) FLICKER DETECTING DEVICE AND FLICKER DETECTING METHOD USING THE SAME, AND RECORDING MEDIUM STORING COMPUTER PROGRAM FOR EXECUTING THE FLICKER DETECTING METHOD

(75) Inventor: Shingo KAWASHIMA, Yongin-City (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Gyunggi-do (KR)

(21) Appl. No.: 12/435,686

(22) Filed: May 5, 2009

(30) Foreign Application Priority Data
Jan. 28, 2009 (KR) 2009-6608

(51) Int. Cl. G01R 13/00; G06F 19/00

(52) U.S. Cl. 702/66

(57) ABSTRACT

A flicker detecting device for detecting a flicker of an organic light emitting diode (OLED) display apparatus, a flicker detecting method that uses the flicker detecting device, and a recording medium storing a computer program executing the flicker detecting method are provided. The flicker detecting device includes a light receiving unit receiving light from the display apparatus and generating a brightness waveform according to a brightness of the light; a frame detecting unit detecting a data display frame of the display apparatus from the brightness waveform; a waveform shaping unit shaping the brightness waveform to eliminate a start period of the data display frame from the brightness waveform; and a flicker calculating unit calculating a flicker value of the display apparatus by using the shaped brightness waveform from the waveform shaping unit, so that the detection of the flicker can be correctly performed.

### CROSS-REFERENCE TO RELATED APPLICATIONS

This application claims the benefit of Korean Patent Application No. 2009-6608, filed Jan. 28, 2009, in the Korean Intellectual Property Office, the disclosure of which is incorporated herein by reference.

### BACKGROUND OF THE INVENTION

1. Field of the Invention

Aspects of the present invention relate to a flicker detecting device, a flicker detecting method that uses the flicker detecting device, and a recording medium storing a computer program for executing the flicker detecting method, and more particularly, to a flicker detecting device for an organic light emitting diode (OLED) display apparatus.

2. Description of the Related Art

Much research has been conducted on display apparatuses such as televisions (TVs) or computer monitors capable of displaying image data, so as to develop various display apparatuses including cathode ray tubes (CRTs), liquid crystal displays (LCDs), plasma display panels (PDPs), organic light emitting diode (OLED) display apparatuses, etc. Such various display apparatuses are continuously improved to allow a user to experience comfort in use.

However, on a display apparatus, a flicker indicates a fading phenomenon in which the screen brightness is not constant and changes according to time. When a user uses a display apparatus that has a severe flicker, the eyes of the user easily feel fatigued or uncomfortable. Thus, researchers use a flicker detecting device to determine whether the flicker has occurred in a display apparatus and to eliminate the flicker.

Conventional flicker detecting devices were developed to detect a flicker of a LCD. Thus, when a flicker of an OLED display apparatus is detected using the conventional flicker detecting device, the reliability of the results is significantly decreased.

FIGS. 1A and 1B are graphs illustrating brightness waveforms generated when a flicker of an OLED display apparatus is detected. Referring to FIG. 1A, the brightness waveform abruptly decreases in every cycle. On the other hand, referring to FIG. 1B, the brightness waveform decreases at a considerably slow rate in every cycle. That is, FIG. 1A corresponds to a case in which a flicker occurs and is recognizable to a user, and FIG. 1B corresponds to a case in which the flicker occurs but is not recognizable to the user.

However, in the case of the OLED display apparatus, a light-off period exists at a start of every frame for displaying data. Since the data is not displayed in the light-off period, brightness abruptly deteriorates temporarily and periodically. It is possible to check whether the abrupt deterioration occurs, as illustrated in FIGS. 1A and 1B. The temporary deterioration of the brightness occurs in a very short period such that a user may not recognize the temporary deterioration of the brightness as a flicker. However, since the conventional flicker detecting device recognizes this temporary deterioration of the brightness as the flicker that occurs while the data is displayed, the conventional flicker detecting device determines that the flicker has occurred in both FIGS. 1A and 1B. Hence, it is difficult to correctly detect the flicker using the conventional flicker detecting device.

### SUMMARY OF THE INVENTION

Aspects of the present invention provide a flicker detecting device, a flicker detecting method that uses the flicker detecting device, and a recording medium storing a computer program for executing the flicker detecting method so that a flicker may be correctly detected in an organic light emitting diode (OLED) display apparatus.

According to an aspect of the present invention, there is provided a flicker detecting device for detecting a flicker of a display apparatus, the flicker detecting device including a light receiving unit receiving light from the display apparatus and generating a brightness waveform according to a brightness of the light; a frame detecting unit detecting a data display frame of the display apparatus from the brightness waveform; a waveform shaping unit shaping the brightness waveform by eliminating a start period of the data display frame from the brightness waveform; and a flicker calculating unit calculating a flicker value of the display apparatus by using the shaped brightness waveform.

The flicker calculating unit may include a waveform separating unit separating the shaped brightness waveform into a direct current (DC) component and an alternating current (AC) component; and a comparing and measuring unit comparing the DC component with the AC component of the shaped brightness waveform, and calculating the flicker value.

The flicker calculating unit may further include a low pass filter (LPF) for receiving the shaped brightness waveform, filtering a high frequency component, and applying the filtered brightness waveform to the waveform separating unit.

The light receiving unit may include a photodiode or a phototransistor.

The display apparatus may include an organic light emitting diode (OLED) display apparatus.

The start period of the data display frame may indicate a light-off period of the OLED display apparatus.

According to another aspect of the present invention, there is provided a flicker detecting method for detecting a flicker of a display apparatus, the flicker detecting method including receiving light from the display apparatus and generating a brightness waveform according to brightness of the light; detecting a data display frame of the display apparatus from the brightness waveform; eliminating a start period of the data display frame from the brightness waveform; and calculating a flicker value of the display apparatus by using the brightness waveform in which the start period of the data display frame is eliminated.

The calculating the flicker value of the display apparatus may include separating the shaped brightness waveform into a direct current (DC) component and an alternating current (AC) component, wherein the start period of the data display frame is eliminated from the brightness waveform; and comparing the DC component with the AC component of the separated brightness waveform, and calculating the flicker value.

Calculating a flicker value of the display apparatus may further include filtering a high frequency component in the brightness waveform in which the start period of the data display frame is eliminated before the separating the brightness waveform into the DC component and the AC component.

In the receiving the light from the display apparatus and the generating the brightness waveform, the brightness waveform may be generated by a photodiode or a phototransistor.

The display apparatus may include an organic light emitting diode (OLED) display apparatus.

The start period of the data display frame may indicate a light-off period of the OLED display apparatus.

According to another aspect of the present invention, there is provided a recording medium storing a program executing the flicker detecting method.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIGS. 1A and 1B are graphs illustrating brightness waveforms generated when a flicker of an organic light emitting diode (OLED) display apparatus is detected;

FIG. 2 is a block diagram of a flicker detecting device according to an embodiment of the present invention;

FIG. 3 is a circuit diagram of a light receiving unit of the flicker detecting device of FIG. 2, according to an embodiment of the present invention;

FIG. 4 is a circuit diagram of a light receiving unit of the flicker detecting device of FIG. 2, according to another embodiment of the present invention;

FIG. 5 is a block diagram of a flicker calculating unit of the flicker detecting device of FIG. 2, according to another embodiment of the present invention; and

FIG. 6 is a flowchart of a flicker detecting method, according to an embodiment of the present invention.

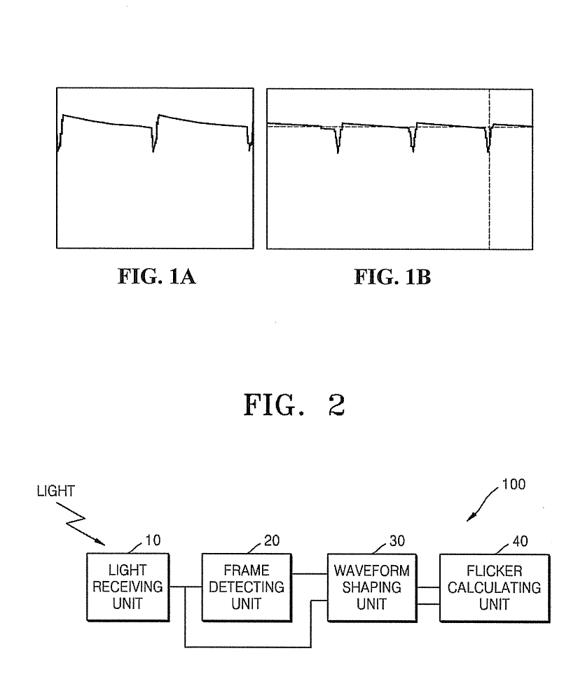

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

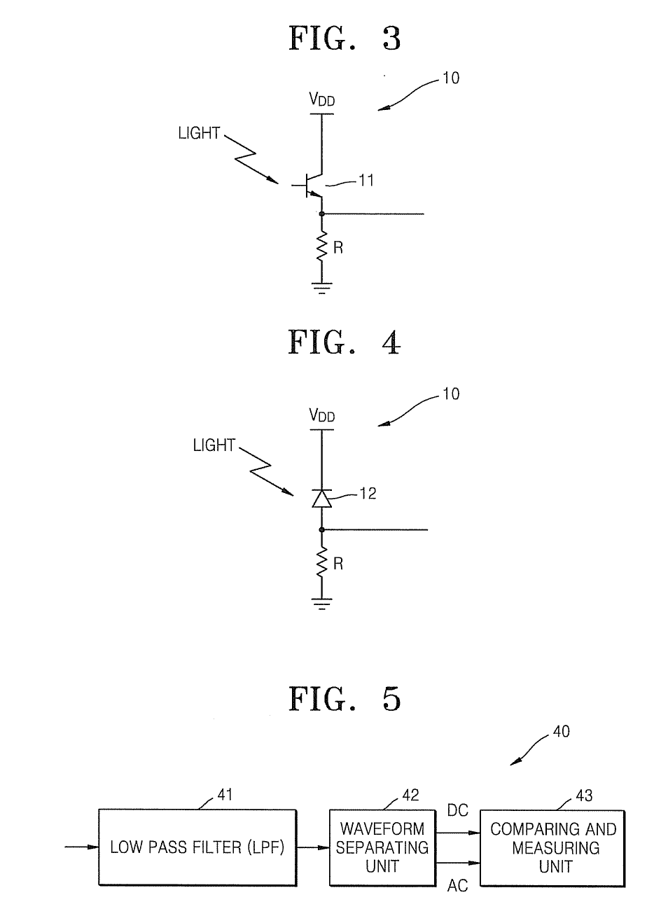

FIG. 2 is a block diagram of a flicker detecting device 100 according to an embodiment of the present invention. FIGS. 3 and 4 are circuit diagrams of a light receiving unit 10 of the flicker detecting device 100 of FIG. 2, according to embodiments of the present invention, and FIG. 5 is a block diagram of a flicker calculating unit 40 of the flicker detecting device 100 of FIG. 2, according to an embodiment of the present invention.

Referring to FIG. 2, the flicker detecting device 100 includes the light receiving unit 10, a frame detecting unit 20, a waveform shaping unit 30, and the flicker calculating unit 40.

The light receiving unit 10 receives light from a display apparatus and thus generates a brightness waveform according to brightness of the light. The display apparatus may be an organic light emitting diode (OLED) display apparatus but aspects of the present invention are not limited thereto and thus the display apparatus may be various display apparatuses such as a cathode ray tube (CRT), a plasma display panel (PDP), a liquid crystal display (LCD), etc.

Meanwhile, referring to FIG. 3, the light receiving unit 10 may include a phototransistor 11. A power voltage VDD may be applied to a first electrode of the phototransistor 11, and a resistor R may be connected between a second electrode of the phototransistor 11 and the ground. Light incident on the phototransistor 11 causes a current flow in the phototransistor 11 and a brightness waveform is generated by detecting the current flowing from the second electrode of the phototransistor 11 to the resistor R or by detecting a voltage of the second electrode of the phototransistor 11, wherein the voltage is generated by the current.

Referring to FIG. 4, the light receiving unit 10 may include a photodiode 12. A power voltage VDD may be applied to a cathode electrode of the photodiode 12, and a resistor R may be connected between an anode electrode of the photodiode 12 and the ground. That is, a reverse bias voltage is applied to the photodiode 12. Light incident on the photodiode 12 causes a current flow from the cathode electrode of the photodiode 12 to the anode electrode of the photodiode 12 and a brightness waveform is generated by detecting the current or a voltage of the anode electrode, wherein the voltage is generated by the current.

The frame detecting unit 20 detects a data display frame of the display apparatus from the brightness waveform generated by the light receiving unit 10. In general, a display apparatus performs time-division on image data and displays the image data. For example, when the image data is displayed at a frequency of 60 Hz, the display apparatus updates and displays the image data in every 1/60 second. Thus, the frame detecting unit 20 calculates a display cycle of the image data, and based on the calculated display cycle, the frame detecting unit 20 detects a time when new image data is displayed and a time when the display of the new image data has ended.

Meanwhile, in the case of the OLED display apparatus, a data display frame of the image data may include a light-off period and a data display period. Thus, when the data display frame is detected, the frame detecting unit 20 may first locate the light-off period and then locate the data display period, and thus, may detect the data display frame.

Although not illustrated in the drawings, the frame detecting unit 20 may directly receive a control signal generated in the display apparatus so as to detect the data display frame. In order to display the image data, the display apparatus generates a horizontal synchronization signal and various control signals synchronized with the horizontal synchronization signal, and the light-off period is formed according to the various control signals. Thus, by applying at least one of the various control signals corresponding to the formation of the light-off period to the frame detecting unit 20, the frame detecting unit 20 may correctly detect the data display frame.

The waveform shaping unit 30 eliminates a start period of the detected data display frame from the brightness waveform generated by the light receiving unit 10, where the start period may be the light-off period.

The flicker calculating unit 40 calculates a flicker of the display apparatus by using the shaped brightness waveform in which the start period of the data display frame is eliminated by the waveform shaping unit 30. Referring to FIG. 5, the flicker calculating unit 40 may include a low pass filter (LPF) 41, a waveform separating unit 42, and a comparing and measuring unit 43.

The LPF 41 receives the brightness waveform from the waveform shaping unit 30, eliminates a high frequency component in the brightness waveform, and only passes a low frequency band signal. A structure of the LPF 41 may use conventional filters according to the related art.

The filtered brightness waveform is applied to the waveform separating unit 42, which separates the brightness waveform into a direct current (DC) component and an alternating current (AC) component. The waveform separating unit 42 may perform a separation operation on a brightness waveform, which has passed the LPF 41 so that a high frequency band signal of the brightness waveform is filtered into a DC component and an AC component. Also, without the filtering by the LPF 41, the waveform separating unit 42 may directly receive the brightness waveform from the waveform shaping unit 30, and thus may perform the separation operation on the directly received brightness waveform.

The comparing and detecting unit 43 compares the DC component with the AC component of the brightness waveform, and calculates a flicker value of the display apparatus. The flicker value may be calculated as a peak-to-peak value of the AC component with respect to the DC component of the brightness waveform. That is, the flicker value may be obtained by V_{dc}/V_{ac(peak-to-peak)}. However, the calculation of the flicker value is not limited thereto and thus the flicker value may be calculated using various methods.

In this manner, with respect to detecting the flicker of the display apparatus, such as the OLED display apparatus, the brightness waveform periodically generated in the light-off period is eliminated so that the detection of the flicker may be correctly performed.

Also, based on the correct detection of the flicker as described above, manufacturing companies may provide users with correct information about the performance of their products so that the users may correctly compare their products with those of different companies.

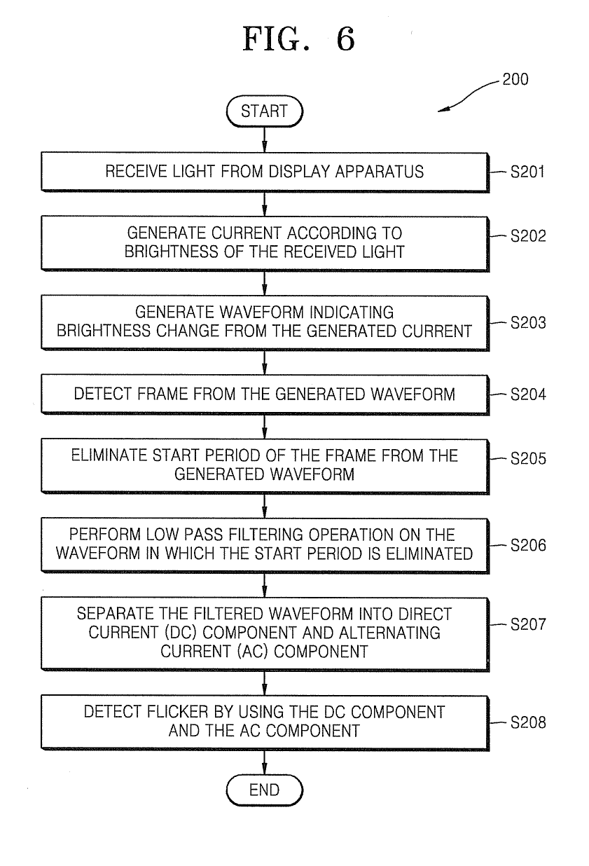

FIG. 6 is a flowchart of a flicker detecting method, according to an embodiment of the present invention.

Referring to FIG. 6, a flicker detecting device receives light from a display apparatus (operation S201), and generates a current according to brightness of the light (operation S202). In order to receive the light and generate the current, the flicker detecting device may include a photodiode or a phototransistor.

Next, a brightness waveform indicating a brightness change is generated from the current (operation S203). The brightness waveform may be a current waveform generated by detecting the current or may be a voltage waveform generated by detecting a voltage generated by the current.

A frame is detected from the brightness waveform (operation S204), where the frame indicates a display unit of image data displayed on the display apparatus. The display apparatus may be an OLED display apparatus, and the frame may include a light-off period and a data display period. As described above with reference to FIG. 2, the frame may be detected directly from the brightness waveform or may be detected by receiving and using a control signal generated in the display apparatus.

After the frame is detected, a start period of the frame is eliminated from the brightness waveform (operation S205), where the start period may be the light-off period.

A low pass filtering operation is performed on the brightness waveform from which the start period is eliminated so that a high frequency band signal is eliminated (operation S206).

The filtered brightness waveform is separated into a DC component and an AC component (operation S207), and a flicker value is calculated by using the DC component and the AC component (operation S208). The calculation of the flicker value may be performed using various methods.

In this manner, with respect to the detection of the flicker of the display apparatus, such as the OLED display apparatus, the flicker may be correctly detected by eliminating the brightness waveform that is periodically generated in the light-off period.

Also, based on the correct detection of the flicker as described above, manufacturing companies may provide users with correct information about the performance of their products so that the users may correctly compare their products with those of different companies.

Meanwhile, a computer program for executing the flicker detecting method according to embodiments of flicker detecting device may be stored in a recording medium. Here, the recording medium may include magnetic storage media (e.g., ROM, floppy disks, hard disks, etc.), optical recording media (e.g., CD-ROMs, or DVDs), non-volatile memory or other similar storage media.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A flicker detecting device for detecting a flicker of a display apparatus, the flicker detecting device comprising:
a light receiving unit receiving light from the display apparatus and generating a brightness waveform according to a brightness of the light;
a frame detecting unit detecting a data display frame of the display apparatus from the brightness waveform;
a waveform shaping unit shaping the brightness waveform to eliminate a start period of the data display frame from the brightness waveform; and
a flicker calculating unit calculating a flicker value of the display apparatus by using the shaped brightness waveform from the waveform shaping unit.

2. The flicker detecting device of claim 1, wherein the flicker calculating unit comprises:
a waveform separating unit separating the shaped brightness waveform into a DC (direct current) component and an AC (alternating current) component; and
a comparing and measuring unit for comparing the DC component with the AC component of the shaped brightness waveform, and calculating the flicker value.

3. The flicker detecting device of claim 2, wherein the flicker calculating unit further comprises a LPF (low pass filter) receiving the shaped brightness waveform, filtering a high frequency component, and applying the filtered brightness waveform to the waveform separating unit.

4. The flicker detecting device of claim 1, wherein the light receiving unit comprises a photodiode or a phototransistor.

5. The flicker detecting device of claim 1, wherein the display apparatus comprises an OLED (organic light emitting diode) display apparatus.

6. The flicker detecting device of claim 5, wherein the start period of the data display frame indicates a light-off period of the OLED display apparatus.

7. A flicker detecting method detecting a flicker of a display apparatus, the flicker detecting method comprising:
receiving light from the display apparatus and generating a brightness waveform according to brightness of the light;
detecting a data display frame of the display apparatus from the brightness waveform;
eliminating a start period of the data display frame from the brightness waveform; and
calculating a flicker value of the display apparatus by using the brightness waveform in which the start period of the data display frame is eliminated.

8. The flicker detecting method of claim 7, wherein the calculating of the flicker value of the display apparatus comprises:
separating the brightness waveform into a DC (direct current) component and an AC (alternating current) component, wherein the start period of the data display frame is eliminated from the brightness waveform; and
comparing the DC component with the AC component of the separated brightness waveform, and calculating the flicker value.

9. The flicker detecting method of claim 8, wherein, the calculating of the flicker value of the display apparatus further comprises filtering a high frequency component in the brightness waveform in which the start period of the data display frame is eliminated before the separating the brightness waveform into the DC component and the AC component.

10. The flicker detecting method of claim 7, wherein, in the receiving of the light from the display apparatus and the generating of the brightness waveform, the brightness waveform is generated by a photodiode or a phototransistor.

11. The flicker detecting method of claim 7, wherein the display apparatus comprises an OLED (organic light emitting diode) display apparatus.

12. The flicker detecting method of claim 11, wherein the start period of the data display frame indicates a light-off period of the OLED display apparatus.

13. A recording medium storing a program executing the flicker detecting method of claim 7.

14. A method of calculating a flicker rate of a display apparatus, the method comprising:
generating a brightness waveform according to an amount of light received from the display apparatus; and
calculating a flicker rate of the display apparatus corresponding to a DC (direct current) component of the generated brightness waveform and an AC (alternating current) component of the generated waveform according to the brightness waveform.

15. The method of claim 14, wherein the generating of the brightness waveform comprises:
generating a current according to an amount light received from the display apparatus;
shaping the generated current to generate the brightness waveform according to a data display frame of image data displayed on display apparatus;
filtering the generated brightness waveform; and
separating the filtered generated brightness waveform into the DC component and the AC component.

16. The method of claim 15, wherein the shaping of the generated current into a brightness waveform comprises:
detecting the data display frame in the generated current by detecting a light-off period; and
eliminating a start period of the detected data display frame to generate the shaped generated brightness waveform.

17. The method of claim 15, wherein the calculating of the flicker rate of the display apparatus comprises measuring and comparing the DC component of the generated brightness waveform to the AC component of the generated brightness waveform.

18. A flicker rate detecting device detecting a flicker rate of a display apparatus, the flicker rate detecting device comprising:
a brightness waveform generator generating a brightness waveform according to an amount of light received from the display apparatus; and
a flicker rate calculator calculating the flicker rate of the display apparatus according to a DC (direct current) component of the generated brightness waveform and an AC (alternating current) component of the generated waveform according to the brightness waveform.

19. The device of claim 18, wherein the brightness waveform generator comprises:
a light receiving unit receiving light from the display apparatus and generating a current according to the amount of light received from the display apparatus;
a frame detecting unit detecting a data display frame of image data in the generated current of the light receiving unit by detecting a light-off period of the image data; and
a waveform shaping unit shaping the generated current to generate the brightness waveform according to the data display frame of image data displayed on display apparatus by eliminating a start period of the detected data display frame to generate a shaped generated brightness waveform.

20. The device of claim 18, wherein the flicker rate calculator of the display apparatus comprises:
a low pass filter filtering the generated brightness waveform;
a waveform separating unit separating the filtered generated brightness waveform into the DC component and the AC component; and
a comparing and measuring unit measuring and comparing the DC component of the generated brightness waveform to the AC component of the generated brightness waveform to calculate the flicker rate of the display apparatus.
